(19) United States
(12) Patent Application Publication
(10) Pub. No.: US 2008/0132050 A1
(43) Pub. Date: Jun. 5, 2008

(54) Deposition process for graded cobalt barrier layers

(76) Inventor: Adrien R. Lavoie, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/634,398

(22) Filed: Dec. 5, 2006

(51) Int. Cl. H01L 21/20

(52) U.S. Cl. 438/584

(57) ABSTRACT

A method for forming a graded cobalt-containing barrier layer comprises forming a cobalt nitride layer on a semiconductor substrate in a reactor, wherein the semiconductor substrate includes a trench etched into a dielectric layer, forming a cobalt metal layer atop the cobalt nitride layer, and then annealing the cobalt nitride layer and the cobalt metal layer to form a graded cobalt barrier layer. A metal layer may be deposited within the trench on the graded cobalt barrier layer to function as a metal interconnect. The cobalt nitride and cobalt metal layers may be formed using PVD, ALD, and/or CVD techniques.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. This gives rise to issues such as trench overhang during the copper seed deposition, leading to pinched-off trench openings during plating and inadequate gapfill. Additionally, as trenches decrease in size, the ratio of barrier metal to copper metal in the overall interconnect structure increases, thereby increasing the electrical line resistance and RC delay of the interconnect.

One approach to addressing these issues is to reduce the thickness of the TaN/Ta or TaN/Ru stack, which widens the available gap for subsequent metallization and increases the final copper volume fraction. Unfortunately, this is often limited by the non-conformal characteristic of PVD deposition techniques. Accordingly, alternative techniques for reducing the thickness of the barrier and adhesion layer are needed.

### BRIEF DESCRIPTION OF THE DRAWINGS

FIGS. 1A to 1B illustrate a conventional damascene process for forming metal interconnects.

FIG. 2 illustrates a graded cobalt-containing barrier layer in accordance with an implementation of the invention.

FIG. 3 is a method for forming a graded cobalt-containing barrier layer and metal interconnect in accordance with an implementation of the invention.

FIG. 4 is a method for forming a cobalt nitride layer and cobalt metal layer using a PVD process in accordance with an implementation of the invention.

FIG. 5 is a method for forming a cobalt nitride layer and cobalt metal layer using an ALD process in accordance with an implementation of the invention.

FIG. 6 is a method for forming a cobalt nitride layer and cobalt metal layer using an ALD co-flow process in accordance with an implementation of the invention.

FIG. 7 is a method for forming a cobalt nitride layer and cobalt metal layer using a CVD/ALD process in accordance with an implementation of the invention.

FIG. 8 is a method for forming a graded cobalt-containing barrier layer in situ using a PVD process in accordance with an implementation of the invention.

FIG. 9 is a method for forming a graded cobalt-containing barrier layer in situ using an ALD process in accordance with an implementation of the invention.

### DETAILED DESCRIPTION

Described herein are methods of fabricating a graded cobalt layer that functions as a barrier layer for a copper interconnect in an integrated circuit application. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention; however, the order of description should not be construed to imply that these operations are necessarily order dependent. In particular, these operations need not be performed in the order of presentation.

Implementations of the invention provide a graded cobalt layer deposited by way of an atomic layer deposition process or a chemical vapor deposition process that may be used to replace the conventional barrier layer and adhesion layer used for copper interconnects in integrated circuit applications. For instance, a graded cobalt layer prepared in accordance with the invention may be used to replace the conventional TaN/Ta or TaN/Ru stack with a single layer. The result is a thinner barrier and adhesion layer that substantially reduces the occurrence of trench overhang and void formation in the copper interconnect. The thinner barrier and adhesion layer also increases the final copper volume fraction of the interconnect, thereby improving electrical line resistance.

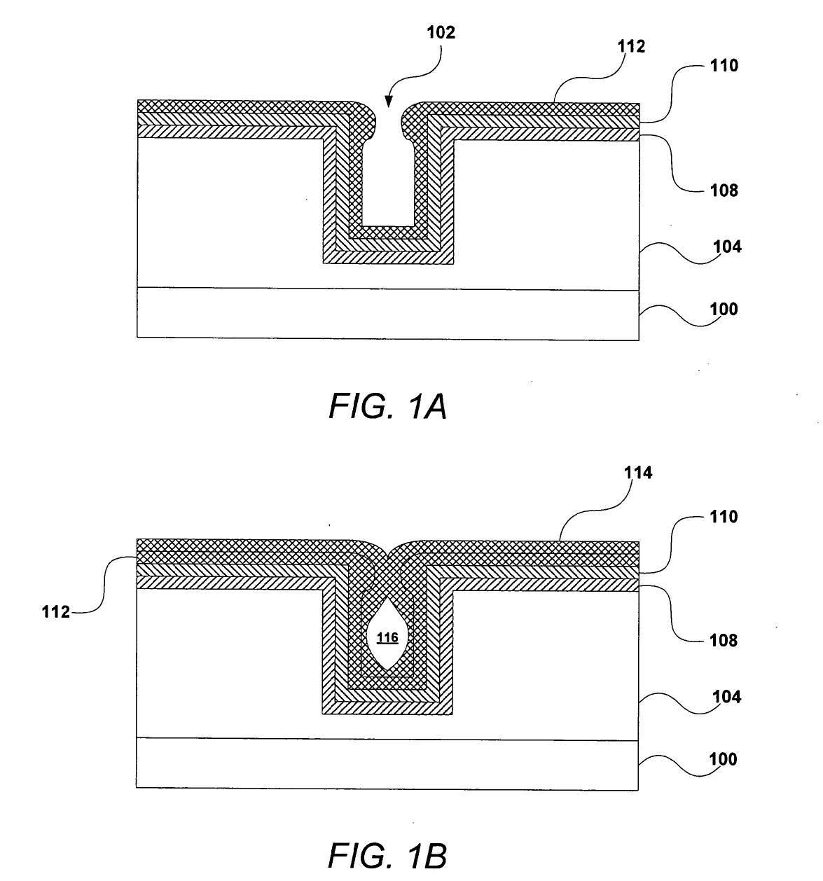

For reference, FIGS. 1A to 1B illustrate a conventional damascene process for fabricating copper interconnects on a semiconductor wafer. FIG. 1A illustrates a substrate 100, such as a semiconductor wafer, that includes a trench 102 that has been etched into a dielectric layer 104. A conventional barrier layer 108 and adhesion layer 110 are conformally deposited on the dielectric layer 104 and within the trench 102. The barrier layer 108 is generally formed from tantalum nitride (TaN) and prevents copper metal from diffusing into the dielectric layer 104. The adhesion layer 110 is generally formed from tantalum (Ta) or ruthenium (Ru) and enables copper metal to become deposited onto the barrier layer 108.

After the adhesion layer 110 is formed, the conventional damascene process uses two independent deposition processes to fill the trench 102 with copper metal. The first deposition process is a PVD process that forms a non-conformal copper seed layer 112, which is shown in FIG. 1A and enables a subsequent plating process to fill the trench 102 with copper metal. As shown, the PVD process may cause some trench overhang to occur in the copper seed layer 112 that narrows the width of the trench 102. The second deposition process is a plating process, such as an electroplating (EP) or electroless plating (EL) process, that deposits a bulk copper layer 114 to fill the trench 102.

FIG. 1B illustrates the trench 102 after an EP or EL copper deposition process has been carried out. Due to the narrow width of the trench 102, issues such as trench overhang and pinching off of the trench opening occur that lead to defects in the plating step. As shown in FIG. 1B, such defects include a void 116 that will now appear in the final metal interconnect after the excess metal disposed outside of the trench 102 is removed during a subsequent planarization step. Furthermore, a substantial portion of the final copper interconnect comprises Ta and/or Ru from the adhesion layer 110 and the barrier layer 108, which decreases the percentage of copper in the final interconnect and increases the RC delay.

In accordance with the invention, novel cobalt-containing precursors are used in a physical vapor deposition (PVD) process, a chemical vapor deposition (CVD) process, or an atomic layer deposition (ALD) process to form a graded, cobalt-containing barrier layer. The cobalt-containing barrier layer inhibits copper diffusion, thereby protecting the underlying dielectric layer from copper used in the copper interconnect. The cobalt-containing barrier layer also enables direct plating of copper on its surface without the need for a copper seed layer. The single cobalt-containing layer may therefore be used to replace the conventional barrier, adhesion, and seed layers described in FIGS. 1A and 1B. Replacing those three layers with a single cobalt-containing barrier layer widens the trench opening, thereby reducing issues such as trench overhang during plating of the bulk copper layer. Use of the cobalt-containing barrier layer also allows for a higher overall copper line volume leading to lower line resistivity and RC delay.

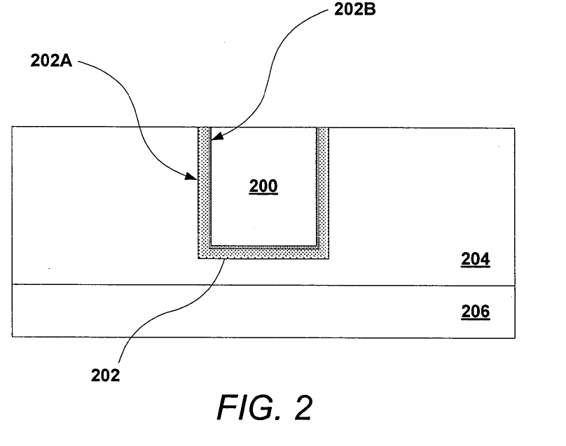

FIG. 2 illustrates a copper interconnect 200 formed within a trench of a dielectric layer 204 upon a substrate 206. The copper interconnect 200 is located within metallization layers of an integrated circuit (IC) die and is used to interconnect transistors and other devices. The substrate 206 may be a portion of a semiconductor wafer. The dielectric layer 204 may be formed using conventional dielectric materials including, but not limited to, oxides such as silicon dioxide (SiO₂) and carbon doped oxide (CDO), silicon nitride, organic polymers such as perfluorocyclobutane (PFCB), and fluorosilicate glass (FSG).

In accordance with an implementation of the invention, a graded cobalt-containing barrier layer 202 is formed between the copper interconnect 200 and the dielectric layer 204. A first portion 202A of the graded cobalt-containing barrier layer 202 proximate to the dielectric layer 204 has a high cobalt nitride concentration and functions as a barrier layer to inhibit copper metal from diffusing into the dielectric layer 204. A second portion 202B of the graded cobalt-containing barrier layer 202 proximate to the copper interconnect 200 has a high cobalt metal concentration to serve as a nucleation site for copper deposition during an electroplating process or an electroless plating process, thereby providing adhesion layer functionality. In implementations of the invention, the graded cobalt-containing barrier layer 202 may have a thickness that ranges from 1 nm to 15 nm.

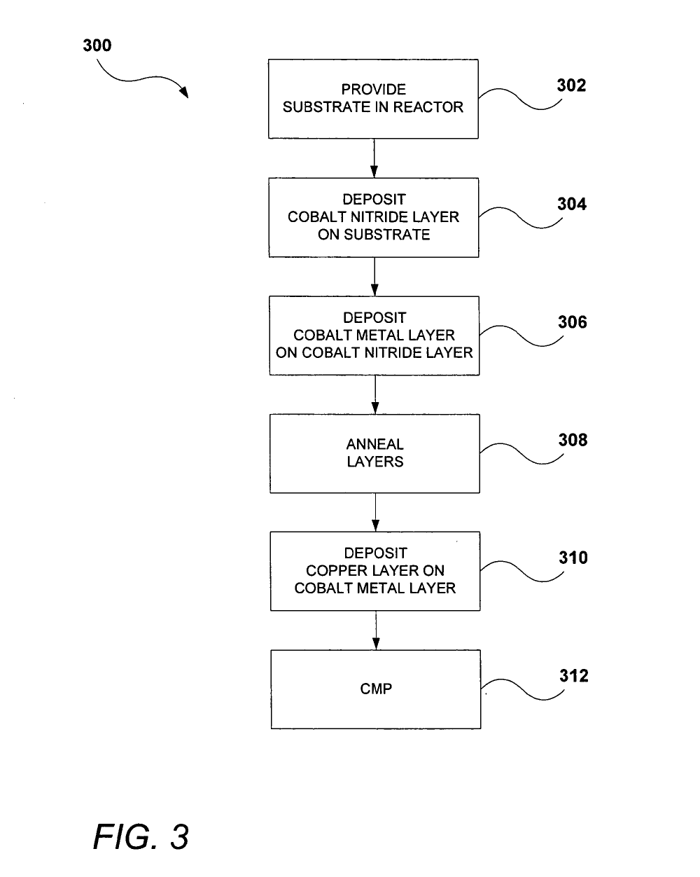

FIG. 3 is a method 300 for fabricating a graded cobalt-containing barrier layer and a metal interconnect in accordance with an implementation of the invention. For ease of reference, the graded cobalt-containing barrier layer will simply be referred to herein as a “Co barrier layer”. The method 300 begins by providing a semiconductor substrate onto which the Co barrier layer and the metal interconnect may be formed (process 302 of FIG. 3). The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group lll-V materials. Although a few examples of materials from which the semiconductor substrate may be formed are described here, any material that may serve as a foundation upon which a semiconductor device may be built falls within the spirit and scope of the present invention.

The substrate has at least one dielectric layer deposited on its surface. The dielectric layer may be formed using materials known for the applicability in dielectric layers for integrated circuit structures, such as low-k dielectric materials. Such dielectric materials include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. The dielectric layer may include one or more trenches and/or vias within which the cobalt-containing layer will be deposited and the metal interconnect will be formed. The trenches and/or vias may be patterned using conventional wet or dry etch techniques that are known in the art.

The substrate may be housed in a reactor in preparation for a PVD process, an ALD process, or a combination of a CVD and an ALD process. In various implementations, the substrate may be heated within the reactor to a temperature between around 50° C. and around 400° C. and the reactor may be heated to a temperature that ranges from 50° C. to 40° C. The pressure within the reactor may range from 0.01 Torr to 3.0 Torr.

Within the reactor, a layer of cobalt nitride is deposited upon the semiconductor substrate (304). The cobalt nitride layer provides barrier functionality to inhibit metal from diffusing out of the metal interconnect and into the underlying dielectric layer. The cobalt nitride layer that is deposited may range in thickness from 0.5 nm to 20 nm.

A layer of cobalt metal is then deposited upon the cobalt nitride layer (306). The cobalt metal layer provides adhesion layer functionality to enable a metal to be deposited directly upon the Co barrier layer. The cobalt metal layer that is deposited may range in thickness from 0.5 nm to 20 nm. In some implementations the cobalt metal layer has substantially the same thickness as the cobalt nitride layer.

As will be described below, in various implementations of the invention, each of the cobalt nitride layer and the cobalt metal layer may be deposited using a PVD process, an ALD process, or a CVD process. In some implementations of the invention, the deposition process used for the cobalt nitride layer may be the same as the deposition process used for the cobalt metal layer, while in other implementations the deposition processes used may differ.

After the cobalt nitride layer and the cobalt metal layer have been deposited, the two layers are optionally subjected to an annealing process (308). The anneal takes place at a temperature that may range from 50° C. to 400° C. for a time duration that may last from 5 seconds to 1200 seconds. During the anneal, a portion of the cobalt nitride diffuses into the cobalt metal layer and a portion of the cobalt metal diffuses into the cobalt nitride layer, thereby merging the layers into a single Co barrier layer and producing graded concentrations of cobalt nitride and cobalt metal across the thickness of the Co barrier layer. The cobalt nitride concentration is highest at a first portion of the Co barrier layer adjacent to the dielectric layer. The cobalt nitride concentration decreases to substantially zero at a second portion of the Co barrier layer where the metal interconnect is deposited. Contrary to this, the cobalt metal concentration is highest at the second portion of the Co barrier layer where the metal interconnect is deposited and decreases to substantially zero at the first portion of the Co barrier layer adjacent to the dielectric layer.

Following the formation of the Co barrier layer, the substrate may be transferred to a reactor containing a plating bath and a plating process may be carried out to deposit a metal layer, such as a copper layer, over the Co barrier layer (310). The copper layer fills the trench to form the copper interconnect. The copper metal enters the trench where, due to the relatively large width of the trench enabled by the thin Co barrier layer, issues such as void formation due to overhang are reduced or eliminated. In some implementations, the plating bath is an electroplating bath and the plating process is an electroplating process in which the copper metal nucleates directly on the second surface of the Co barrier layer due to the high concentration of cobalt metal. In other implementations, the plating bath is an electroless plating bath and the plating process is an electroless plating process in which the copper metal again nucleates directly on the second surface of the Co barrier layer due to the high concentration of cobalt metal.

In further implementations, a copper seed layer may be deposited using an electroless plating process before the copper layer is deposited. Alternately, a copper seed layer may be deposited using a CVD or an ALD process prior to filling the trench using an electroplating or electroless plating process. In yet another implementation, the CVD or ALD process may be used to fill the entire trench with copper to form the copper interconnect. Finally, a chemical mechanical polishing (CMP) process may be used to planarize the deposited copper metal and finalize the copper interconnect structure (312).

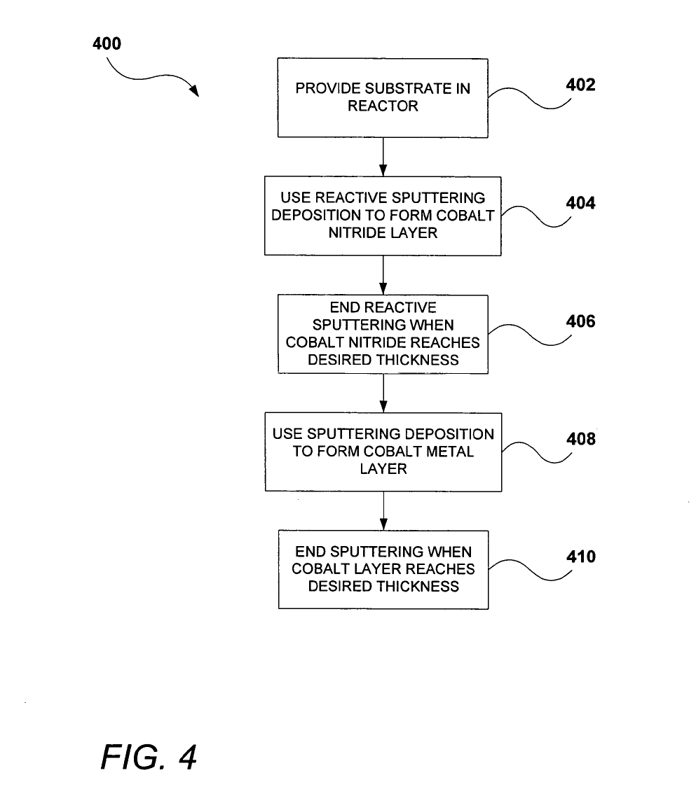

As mentioned above, each of the cobalt nitride layer and the cobalt metal layer may be formed using a PVD process, an ALD process, or a CVD process. In accordance with one implementation of the invention, a PVD process may be used to form the cobalt nitride layer and the cobalt metal layer. FIG. 4 is a PVD method 400 for generating a cobalt nitride layer and a cobalt metal layer in accordance with an implementation of the invention. The method 400 begins with a semiconductor substrate as described above housed in a PVD reactor (402). The substrate may be heated within the reactor to a temperature between around 25° C. and around 250° C. and the reactor may be heated to a temperature that ranges from 25° C. to 250° C. The pressure within the reactor may range from 0.005 Torr to 3.0 Torr.

Next, a reactive sputtering of cobalt with nitrogen (N₂) or ammonia (NH₃) is employed to generate a cobalt nitride layer (404). The stoichiometric ratio of cobalt to nitrogen may be modulated by attenuating the flow of N₂ or NH₃ or by dilution with a carrier gas such as helium (He) or argon (Ar). The reactive sputtering of cobalt with N₂ or NH₃ continues until the cobalt nitride layer has reached a desired thickness (406). In some implementations, this the desired thickness of the cobalt nitride layer may range from 0.5 nm to 20 nm.

The flow of N₂ or NH₃ may then be halted and the method 400 continues with a sputtering deposition of cobalt in the presence of the carrier gas to generate a cobalt metal layer atop the cobalt nitride layer (408). This process continues until the cobalt metal layer has reached a desired thickness (410). In some implementations, the desired thickness of the cobalt metal layer may range from 0.5 nm to 20 nm. The PVD method 400 may be incorporated into the method 300 to form the cobalt nitride and cobalt metal layers that are subsequently annealed to form a graded Co barrier layer in accordance with implementations of the invention.

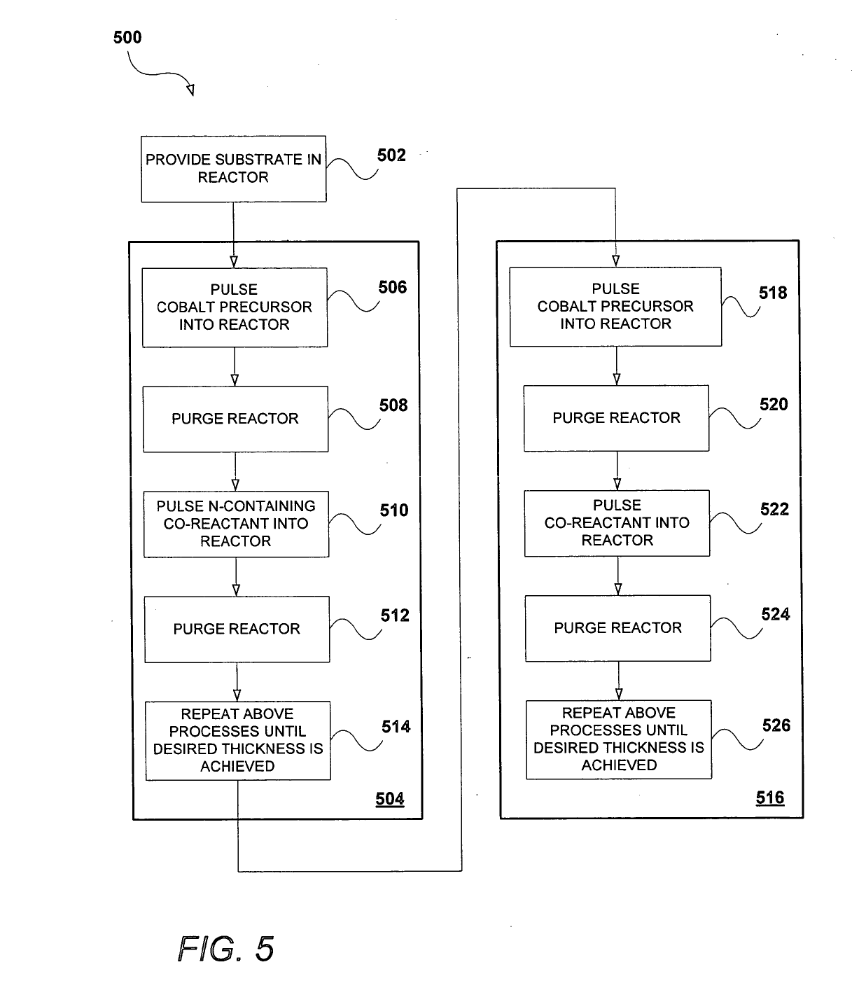

In accordance with another implementation of the invention, an ALD process may be used to form the cobalt nitride layer and the cobalt metal layer. FIG. 5 is a method 500 of forming an ALD cobalt nitride layer and an ALD cobalt metal layer according to an implementation of the invention. The method begins with a semiconductor substrate housed in an ALD reactor (502). The substrate may be heated within the reactor to a temperature between around 25° C. and around 250° C. and the reactor may be heated to a temperature that ranges from 25° C. to 250° C. The pressure within the reactor may range from 0.01 Torr to 3.0 Torr.

One or more ALD process cycles are then used to deposit a cobalt nitride layer (504). This process cycle usually begins with at least one pulse of a cobalt precursor that is introduced into the reactor (506). In accordance with implementations of the invention, the cobalt (Co) precursor used to form the cobalt nitride layer may be chosen from the following group of precursors: tetracarbonyl derivatives that include, but are not limited to, (H)CO(CO)₄, (Me)Co(CO)₄ (where Me=methyl), (Et)Co(CO)₄ (where Et=ethyl), and (acetyl)Co(CO)₄; tricarbonyl derivatives that include, but are not limited to, (allyl)CO(CO)₃, (1,3 butadiene)CO(CO)₃, crotyl(1-3 butenyl)CO(CO)₃, and CO(CO)₃(NO); dicarbonyl derivatives that include, but are not limited to, CO(CO)₂(cycloheptadienyl), [(MeO)₃P]₂CoMe(CO)₂, Me₃Si(Cp)CO(CO)₂; cyclopentadienyl (Cp) containing precursors or derivatives that include, but are not limited to, Cp₂Co (cobaltocene), CPCO(CO)₂, CpCo(hexadiene), CpCo(MeCp), Cp(Co)(CH₃CN), CpCo(PMe₃)₂, CpCo(norboradiene), CpCo(RCp) (where RCp is any derivatized cyclopentadienyl ligand), CpCo(R) [where R═COD (where COD=cyclooctadiene), norbornadiene, or two olefins such as ethylene], Cp(Co)duroquinone, and (CO)₂(Cp)CO; and other cobalt containing precursors that include, but are not limited to, Co(II)acetylacetonate, bis(N,N′-diisopropylacetamidinato)Co(II), bis(N,N′-disecbutylacetamidinato)Co(II), tris(2,2,6,6-tetramethyl-3,5-heptanedionato)Co(III), Co(allyl)₃, Co(1-methyl-allyl)₃, allylCo(PMe₃)₃, allylCo(CO)(PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (indenyl)₂Co. In some implementations of the invention, the above listed precursors may be modified by mixing of the ratio of ligands or substituting analogues of ligands. In other implementations, more than one of the cobalt precursors, each having different ligands, may be used simultaneously in the ALD process.

In various implementations of the invention, the following process parameters may be used for the cobalt precursor pulse. The cobalt precursor pulse may have a duration that ranges from around 0.5 second to around 10 seconds with a flow rate of up to 10 standard liters per minute (SLM). The specific number of cobalt precursor pulses may range from 1 pulse to 200 pulses or more depending on the desired thickness of the final cobalt nitride layer. The cobalt precursor temperature may be between around 60° C. and 250° C. The vaporizer temperature may be around 60° C. to around 250° C.

A heated carrier gas may be employed to move the cobalt precursor, with a temperature that generally ranges from around 50° C. to around 200° C. Carrier gases that may be used here include, but are not limited to, Ar, Xe, He, H₂, N₂, forming gas, or mixture of these gases. The flow rate of the carrier gas may range from around 100 SCCM to around 300 SCCM.

The precursor delivery line into the reactor may be heated to a temperature that ranges from around 60° C. to around 250° C., or alternately, to a temperature that is at least 25° C. hotter than the volatile precursor flow temperature within the delivery line to avoid condensation of the precursor. Generally the delivery line temperature may be around 100° C. to around 180° C. Before discharge, the delivery line pressure may be set to around 0 to 5 psi, the orifice may be between 0.1 mm and 1.0 mm in diameter, and the charge pulse may be between 0.5 seconds and 5 seconds. The equilibration time with the valves closed may be 0.5 seconds to 5 seconds and the discharge pulse may be 0.5 seconds to 5 seconds.

Finally, an RF energy source may be applied at a power that ranges from 5 W to 200 W and at a frequency of 13.56 MHz, 27 MHz, or 60 MHz. It should be noted that the scope of the invention includes any possible set of process parameters that may be used to carry out the implementations of the invention described herein.

After the at least one pulse of the cobalt precursor, the reactor may be purged (508). The purge gas may be an inert gas such as Ar, Xe, N₂, He, or forming gas and the duration of the purge may range from 0.1 seconds to 60 seconds, depending on the ALD reactor configurations and other deposition conditions. In most implementations of the invention, the purge may range from 0.5 seconds to 10 seconds.

In accordance with an implementation of the invention, at least one pulse of a nitrogen containing co-reactant is introduced into the reactor to react with the cobalt precursor (510). In some implementations the co-reactant may be nitrogen (N₂), ammonia (NH₃), trimethylamine (NMe₃), or triethylamine (NEt₃). Conventional process parameters may be used for the co-reactant pulse. For instance, in implementations of the invention, the process parameters for the co-reactant pulse include, but are not limited to, a co-reactant pulse duration of between around 0.5 seconds and 10 seconds, a co-reactant flow rate of up to 10 SLM, a reactor pressure between around 0.05 Torr and 3.0 Torr, a co-reactant temperature between around 80° C. and 200° C., a substrate temperature between around 100° C. and around 400° C., and an RF energy source that may be applied at a power that ranges from 5 W to 200 W and at a frequency of 13.56 MHz, 27 MHz, or 60 MHz. It should be noted that the scope of the invention includes any possible set of process parameters that may be used to carry out the implementations of the invention described herein.

After the at least one pulse of the co-reactant, the reactor may again be purged (512). The purge gas may be an inert gas such as Ar, Xe, N₂, He, or forming gas and the duration of the purge may range from 0.1 seconds to 60 seconds, depending on the ALD reactor configurations and other deposition conditions. In most implementations of the invention, the purge may range from 0.5 seconds to 10 seconds.

The above processes result in the formation of a cobalt nitride layer on the dielectric layer. If the cobalt nitride layer has not yet reached a desired thickness, the above processes may be repeated as necessary until the desired thickness is reached (514).

Next, one or more ALD process cycles are used to deposit a cobalt metal layer atop the cobalt nitride layer (516). The cobalt metal process cycle usually begins with at least one pulse of a cobalt precursor that is introduced into the reactor (518). Again, Co precursors that may be used include, but are not limited to, tetracarbonyl derivatives that include, but are not limited to, (H)CO(CO)₄, (Me)Co(CO)₄, (Et)Co(CO)₄, and (acetyl)CO(CO)₄; tricarbonyl derivatives that include, but are not limited to, (allyl)CO(CO)₃, (1,3 butadiene)CO(CO)₃, crotyl(1-3 butenyl)Co(CO)₃, and Co(CO)₃(NO); dicarbonyl derivatives that include, but are not limited to, CO(CO)₂(cycloheptadienyl), [(MeO)₃P]₂CoMe(CO)₂, Me₃Si(Cp)CO(CO)₂; cyclopentadienyl (Cp) containing precursors or derivatives that include, but are not limited to, Cp₂Co (cobaltocene), CpCo(CO)₂, CpCo(hexadiene), CpCo(MeCp), Cp(Co)(CH₃CN), CpCo(PMe₃)₂, CpCo(norboradiene), CpCo(RCp) (where RCp is any derivatized cyclopentadienyl ligand), CpCo(R) (where R═COD, norbornadiene, or two olefins such as ethylene), Cp(Co)duroquinone, and (CO)₂(CP)Co; and other cobalt containing precursors that include, but are not limited to, Co(II)acetylacetonate, bis(N,N′-diisopropylacetamidinato)Co(II), bis(N,N′-disecbutylacetamidinato)Co(II), tris(2,2,6,6-tetramethyl-3,5-heptanedionato)Co(III), CO(allyl)₃, Co(1-methyl-allyl)₃, allylCo(PMe₃)₃, allylCo(CO) (PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (indenyl)₂Co.

In various implementations of the invention, the process parameters provided above may be used for this cobalt precursor pulse. For instance, the cobalt precursor pulse may range from around 0.5 second to around 10 seconds with a flow rate of up to 10 standard liters per minute (SLM), with the specific number of cobalt precursor pulses ranging from 1 pulse to 200 pulses or more depending on the desired thickness of the final cobalt metal layer.

After the at least one pulse of the cobalt precursor, the reactor may be purged (520). Then at least one pulse of a co-reactant may be introduced into the reactor to react with the cobalt precursor (522). In implementations of the invention, the co-reactant may be hydrogen (H₂) or carbon monoxide (CO). Conventional process parameters may be used for the co-reactant pulse, such as the co-reactant process parameters provided above. For instance, the co-reactant pulse may have a duration of between around 0.5 seconds and 10 seconds at a flow rate of up to 10 SLM.

In further implementations, a plasma may be used as a co-reactant. For instance, a hydrogen plasma may be employed as a co-reactant in addition to or in lieu of the H₂ co-reactant provided above. If a hydrogen plasma is used as the co-reactant, process parameters that may be used include a flow rate of around 200 SCCM to around 600 SCCM, though the hydrogen plasma flow rate will generally be around 300 SCCM. The hydrogen plasma may be pulsed into the reactor with a pulse duration of around 0.5 seconds to around 4.0 seconds, with a pulse duration of around 1 to 4 seconds often being used. The plasma power may range from around 20 W to around 500 W and will generally range from around 60 W to around 200 W. A carrier gas such as helium, argon, or xenon may be used to introduce the plasma. A chuck upon which the semiconductor substrate is mounted may be biased and capacitively-coupled.

It should be noted that the scope of the invention includes any possible set of process parameters that may be used to carry out the implementations of the invention described herein. After the at least one pulse of the co-reactant, the reactor may again be purged (524). The above processes result in the formation of a cobalt metal layer on the cobalt nitride layer. If the cobalt metal layer has not yet reached a desired thickness, the above processes may be repeated as necessary until the desired thickness is achieved (526). Again, the ALD method 500 may be incorporated into the method 300 to form the cobalt nitride and cobalt metal layers that are subsequently annealed to form a graded Co barrier layer in accordance with implementations of the invention.

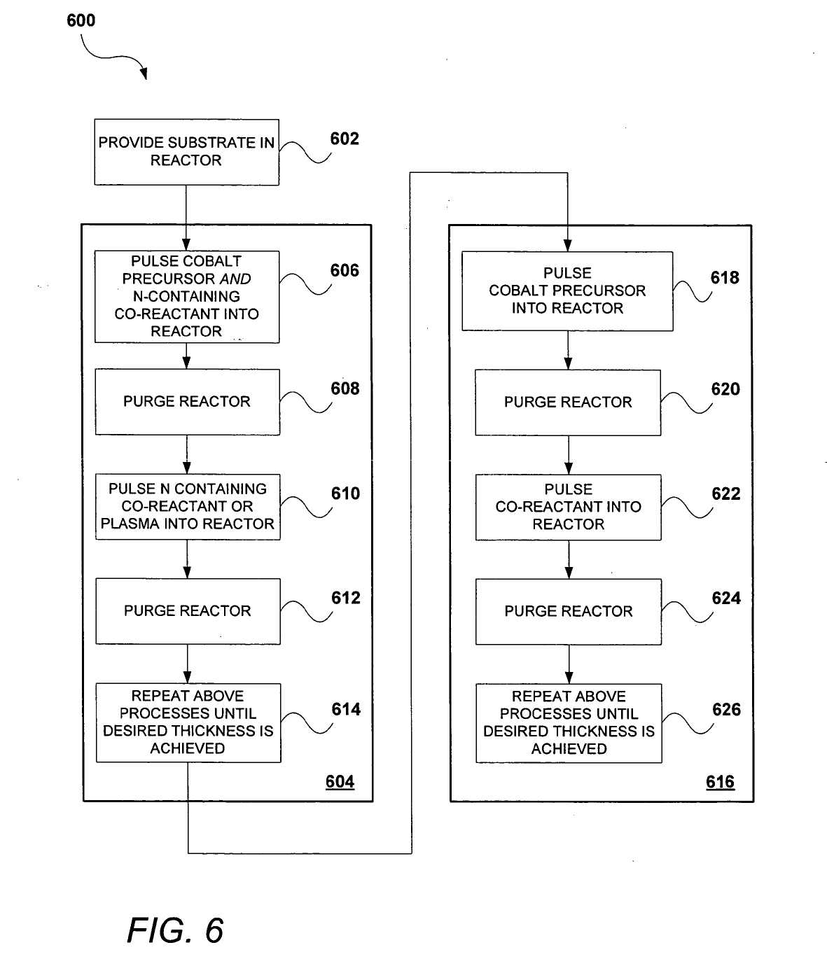

In accordance with another implementation of the invention, an ALD co-flow process may be used to form the cobalt nitride layer and the cobalt metal layer. FIG. 6 is an ALD co-flow method 600 of forming the cobalt nitride layer and the cobalt metal layer according to an implementation of the invention. As shown, after providing a substrate (602), a first process cycle 604 begins by pulsing of two materials into the reactor at substantially the same time, a cobalt precursor and a nitrogen-containing co-reactant such as N₂ or NH₃ (606). The cobalt precursors and process parameters provided above may be used here. Next, the reactor is purged (608) and a co-reactant such as N₂, NH₃, or a hydrogen plasma may be pulsed into the reactor (610). The co-reactant process parameters and plasma parameters described above may be used here. The reactor may again be purged (612) and the process cycle 604 may be repeated until the cobalt nitride layer reaches a desired thickness (614).

After the cobalt nitride layer is formed, a process cycle 616 may be carried out to form a cobalt metal layer on the cobalt nitride layer. This process cycle 616 may be substantially identical to the process cycle 516 described above for forming an ALD cobalt metal layer, specifically process steps 518 through 526 of FIG. 5. Accordingly, the process cycle 616 includes pulsing a cobalt precursor into the reactor (618), purging the reactor (620), pulsing a co-reactant such as hydrogen or a hydrogen plasma into the reactor (622), and purging the reactor again (624). The process cycle 616 may be repeated until the cobalt metal layer reaches a desired thickness (626). Again, the process parameters provided above for the process of FIG. 5 may be used here. Again, the ALD co-flow method 600 may be incorporated into the method 300 to form the cobalt nitride and cobalt metal layers that are subsequently annealed to form a graded Co barrier layer in accordance with implementations of the invention.

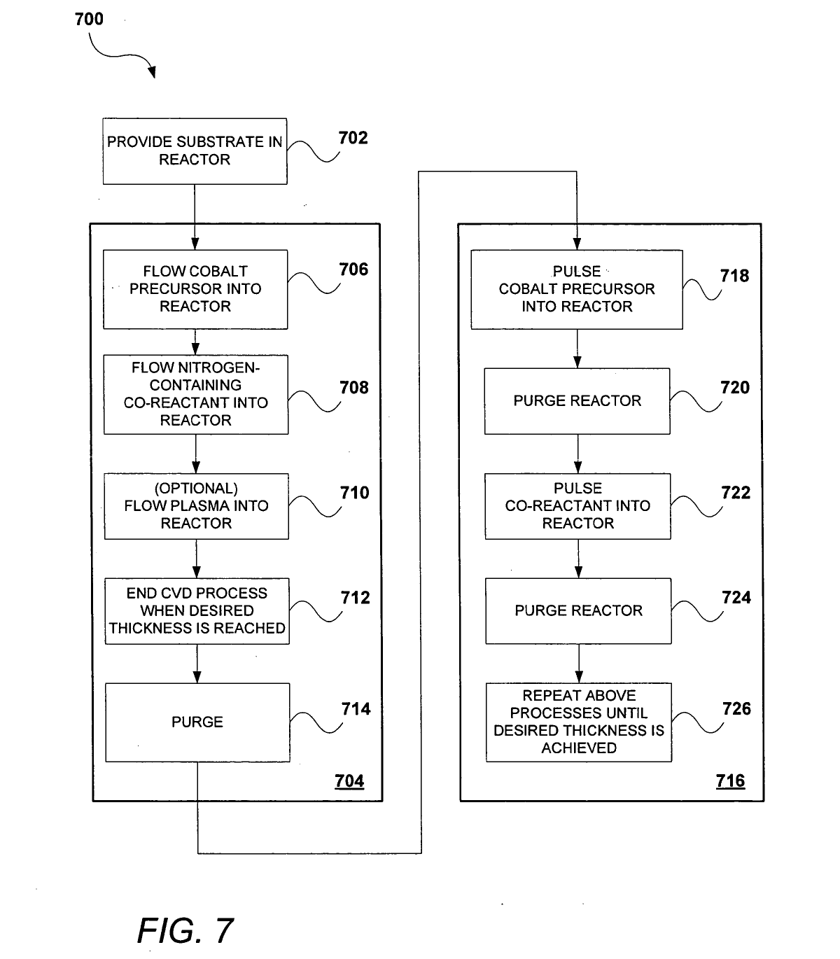

According to another implementation of the invention, a CVD and ALD process may be used to form the cobalt nitride layer and cobalt metal layer. FIG. 7 is such a method 700 in which a CVD cobalt nitride layer is formed, followed by an ALD cobalt metal layer. The method 700 begins with a semiconductor substrate housed in an CVD/ALD reactor (702). The substrate may be heated within the reactor to a temperature between around 25° C. and around 350° C. and the reactor may be heated to a temperature that ranges from 25° C. to 250° C. The pressure within the reactor may range from 0.01 Torr to 3.0 Torr.

A CVD process is then carried out to form a cobalt nitride layer (704). The CVD process introduces a cobalt precursor flow into the reactor (706), while simultaneously introducing a nitrogen-containing co-reactant flow into the reactor (708). The cobalt precursor and nitrogen-containing co-reactant react to generate a cobalt nitride layer. Possible co-reactants include, but are not limited to, nitrogen (N₂), ammonia (NH₃), trimethylamine (NMe₃), or triethylamine (NEt₃). Possible cobalt precursor include, but are not limited to, tetracarbonyl derivatives that include, but are not limited to, (H)Co(CO)₄, (Me)Co(CO)₄, (Et)CO(CO)₄, and (acetyl)Co(CO)₄; tricarbonyl derivatives that include, but are not limited to, (allyl)CO(CO)₃, (1,3 butadiene)Co(CO)₃, crotyl(1-3 butenyl)Co(CO)₃, and Co(CO)₃(NO); dicarbonyl derivatives that include, but are not limited to, CO(CO)₂(cycloheptadienyl), [(MeO)₃P]₂CoMe(CO)₂, Me₃Si(Cp)Co(CO)₂; cyclopentadienyl (Cp) containing precursors or derivatives that include, but are not limited to, Cp₂CO (cobaltocene), CpCo(CO)₂, CpCo(hexadiene), CpCo(MeCp), Cp(Co)(CH₃CN), CpCo(PMe₃)₂, CpCo(norboradiene), CpCo(RCp) (where RCp is any derivatized cyclopentadienyl ligand), CpCo(R) (where R═COD, norbornadiene, or two olefins such as ethylene), Cp(Co)duroquinone, and (CO)₂(Cp)CO; and other cobalt containing precursors that include, but are not limited to, Co(II)acetylacetonate, bis(N,N′-diisopropylacetamidinato)Co(II), bis(N,N′-disecbutylacetamidinato)Co(II), tris(2,2,6,6-tetramethyl-3,5-heptanedionato)Co(III), Co(allyl)₃, Co(1-methyl-allyl)₃, allylCo(PMe₃)₃, allylCo(CO) (PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (indenyl)₂Co.

In further implementations of the invention, the CVD process may introduce a plasma flow into the reactor in addition to the cobalt precursor and co-reactant flows (710). The plasma used may include, but is not limited to, a hydrogen plasma, a nitrogen plasma, and an ammonia plasma. The plasma may be introduced by way of a carrier gas such as helium, argon, or xenon.

Conventional process parameters may be used for the cobalt precursor flow and the co-reactant flow. For instance, in various implementations of the invention, the following process parameters may be used for the cobalt nitride CVD process. The cobalt precursor and the co-reactant may each have a flow rate of up to 10 SLM. The cobalt precursor temperature may be between around 80° C. and 250° C. and the vaporizer temperature may be around 60° C. to around 250° C. The co-reactant temperature may be between around 80° C. and 200° C. A heated carrier gas may be employed to move the cobalt precursor and/or the co-reactant with a temperature that generally ranges from around 60° C. to around 200° C. and a flow rate that ranges from around 100 SCCM to around 200 SCCM. If a plasma is introduced, the plasma power may range from 20 W to 500 W and a chuck holding the substrate may be biased and capacitively-coupled.

The delivery lines into the reactor may be heated to a temperature that ranges from around 60° C. to around 250° C., or alternately, to a temperature that is at least 25° C. hotter than the volatile precursor flow temperature within the delivery line to avoid condensation of the precursor. Generally the delivery line temperature may be around 120° C. to 180° C.

In some implementations, an RF energy source may be applied at a power that ranges from 5 W to 200 W and at a frequency of 13.56 MHz, 27 MHz, or 60 MHz. It should be noted that the scope of the invention includes any possible set of process parameters that may be used to carry out the implementations of the invention described herein.

The CVD process continues flowing the cobalt precursor and the co-reactant into the reactor until the cobalt nitride layer reaches a desired thickness. Once the desired thickness is achieved, the flow of cobalt precursor and co-reactant is halted (712). The reactor may then be purged (714). The purge gas may be an inert gas such as Ar, Xe, N₂, He, or forming gas and the duration of the purge may range from 0.1 seconds to 60 seconds, depending on the CVD/ALD reactor configurations and other deposition conditions. In most implementations of the invention, the purge may range from 0.5 seconds to 10 seconds. The CVD process 704 therefore results in the formation of a cobalt nitride layer on the dielectric layer.

After the cobalt nitride layer is formed, an ALD process cycle 716 may be carried out to form a cobalt metal layer on the cobalt nitride layer. This process cycle 716 may be substantially identical to the process cycle 516 described above for forming an ALD cobalt metal layer, specifically process steps 518 through 526 of FIG. 5. Accordingly, the process cycle 716 includes pulsing a cobalt precursor into the reactor (718), purging the reactor (720), pulsing a co-reactant such as hydrogen or a hydrogen plasma into the reactor (722), and purging the reactor again (724). The process cycle 716 may be repeated until the cobalt metal layer reaches a desired thickness (726). Again, the process parameters provided above for the process of FIG. 5 may be used here. The CVD/ALD method 700 may be incorporated into the method 300 to form cobalt nitride and cobalt metal layers that may be annealed to form a graded Co barrier layer in accordance with implementations of the invention.

In alternate implementations of the invention, a graded Co barrier layer may be formed in situ by manipulating process parameters such as precursor mixing and plasma conditions during the deposition process. For instance, the cobalt nitride concentration may be controlled by way of the ratio of reactants and/or the plasma process parameters. In further implementations of the invention, the process parameters for the multiple process cycles may be varied to change the cobalt nitride concentration across the thickness of the Co barrier layer. For instance, changing the parameters of each individual process cycle, or groups of successive process cycles, may be used to fabricate a Co barrier layer that has a tailored nitrogen concentration gradient.

In various implementations of the invention, process parameters that may be manipulated to establish a cobalt nitride concentration gradient and/or a cobalt metal concentration gradient within the Co barrier dyer include, but are not limited to, the specific precursors that are used in each process cycle, how long each precursor is flowed into the reactor during a process cycle, the precursor concentration and flowrate during each process cycle, the co-reactant used, how long each co-reactant is flowed into the reactor during a process cycle, the co-reactant concentration and flowrate during each process cycle, the sequence or order of the precursor and co-reactant, the plasma energy applied (if any), the substrate temperature, the pressure within the reaction chamber, and the carrier gas composition. The various cobalt precursors used to fabricate a graded Co barrier layer may include the novel cobalt precursors listed above.

Forming the graded Co barrier layer in situ eliminates the need to deposit separate cobalt nitride and cobalt metal layers and then annealing such layers. Accordingly, the methods provided below for forming a graded Co barrier layer may be incorporated into the method 300 above to replace the processes that form and anneal the separate cobalt nitride and cobalt metal layers (i.e., the processes disclosed below may be used to replace the processes 304 through 308 of FIG. 3).

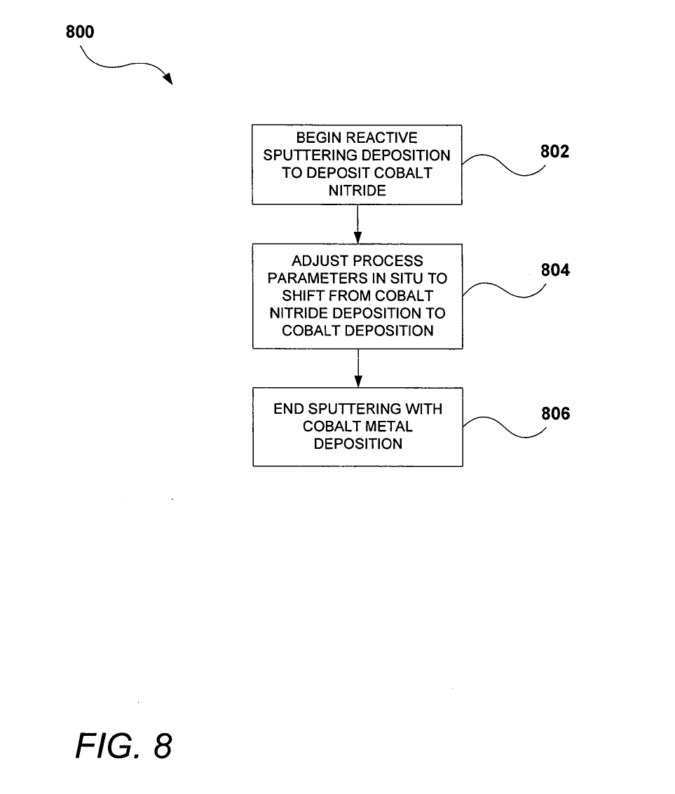

FIG. 8 is a PVD method 800 for fabricating a graded Co barrier layer in accordance with an implementation of the invention. Given a substrate onto which the Co barrier layer may be formed, the method 800 begins with a reactive sputtering of cobalt with nitrogen (N₂) or ammonia (NH₃) to deposit cobalt nitride onto the substrate (802). This initial portion of the sputtering process forms a layer that is high in cobalt nitride to function as a barrier layer.

As the sputtering continues, the stoichiometric ratio of cobalt to nitrogen is adjusted, in situ, to progressively increase the amount of cobalt relative to nitrogen (804). In some implementations, this may be done by attenuating the flow of N₂ or NH₃ into the reactor. In other implementations, this may be done by diluting the nitrogen through the addition of a carrier gas. Thus, as the thickness of the Co barrier layer continues to increase, this in situ adjustment creates a decreasing cobalt nitride concentration and an increasing cobalt metal concentration.

A final portion of the sputtering process is eventually reached where the flow of nitrogen containing co-reactant is substantially halted, thereby allowing a cobalt metal to be deposited (806). The nitrogen concentration is minimal or zero, and this cobalt metal portion of the Co barrier layer functions as an adhesion layer for the subsequent deposition of copper or another metal. Accordingly, manipulating the PVD process conditions are provided herein generates a Co barrier layer that has graded concentrations of cobalt metal and cobalt nitride across its thickness.

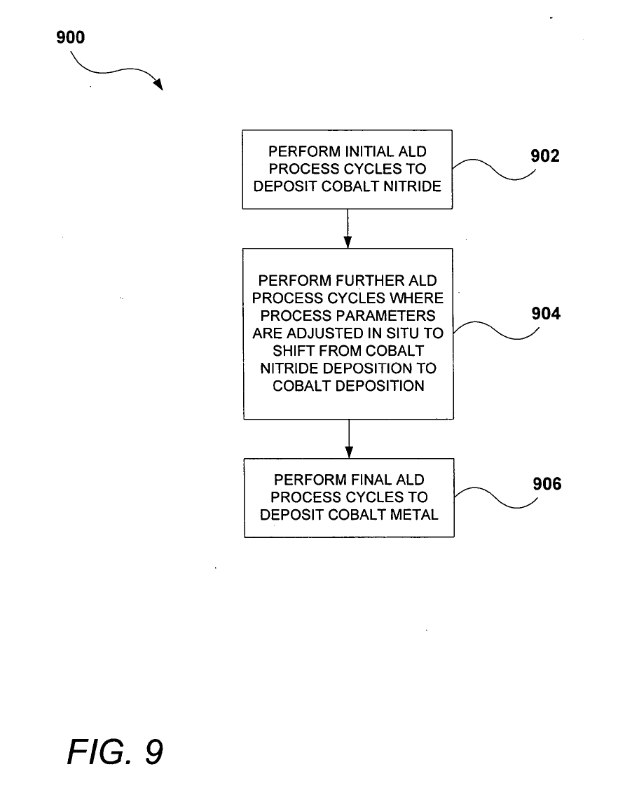

FIG. 9 is an ALD method 900 of fabricating a graded Co barrier layer in accordance with another implementation of the invention. Given a substrate onto which the Co barrier layer may be formed, the method 900 begins with one or more initial ALD process cycles that deposit cobalt nitride onto the substrate (902). The reactants for the initial process cycles are one or more of the cobalt precursors provided above and nitrogen containing co-reactants such as N₂ or NH₃. In further implementations, an ALD co-flow process as described above may be used where the cobalt precursor is pulsed together with N₂, NH₃, NME₃, or NEt₃. Process parameters provided for the ALD and ALD co-flow processes described above may be implemented here. The initially deposited cobalt nitride yields barrier layer functionality.

A series of ALD process cycles are then carried out in which the stoichiometric ratio of cobalt to nitrogen is adjusted, in situ, to progressively increase the amount of cobalt relative to nitrogen (904). There are several methods that may be used to do this. In some implementations, this may be done by attenuating the nitrogen co-reactant flow into the reactor. For instance, over a series of consecutive ALD process cycles, the number of co-reactant pulses may be decreased or the duration of each pulse may be shortened. In some implementations, over a series of process cycles, the co-reactant may be gradually diluted or gradually replaced with an alternate co-reactant such as hydrogen. In some implementations, if an ALD co-flow process is used, the nitrogen containing co-reactant that is combined with the cobalt precursor may be attenuated as well. In further implementations, if a plasma is being applied, the plasma power may be adjusted or the temperature may be increased over a series of process cycles to cause at least some of the cobalt precursor to decompose and form cobalt metal rather than reacting to form cobalt nitride.

A final set of ALD process cycles are then carried out in which a cobalt metal layer is formed (906). The cobalt precursors described above, as well as the process parameters described above, may be used here. The cobalt metal layer provides adhesion layer functionality for the Co barrier layer.

In further implementations of the invention, graded Co barrier layers may be formed in situ using CVD and ALD methods. For instance, the CVD/ALD process 700 described above may be manipulated in situ to form a graded Co barrier layer. In such a process, the flow of nitrogen containing co-reactants may be attenuated during the CVD process to grade the cobalt nitride layer that is being deposited. As the flow of nitrogen containing co-reactants is gradually decreased, the concentration of cobalt metal will increase. The ALD process may then follow to continue the gradual grading to cobalt metal, or it may be used to simply deposit pure cobalt metal on the CVD formed Co barrier layer.

Accordingly, PVD, ALD, and CVD processes have been described that enable the growth of graded Co barrier layers that may be used in sub-100 nm VLSI interconnect structures. The resulting Co barrier layer has properties allowing direct copper plating without the need for an additional copper seed layer while still functioning as a barrier to copper diffusion. Furthermore, the processes described herein takes place at temperatures that are compatible with back-end semiconductor process technologies (i.e., less than 400° C.). And finally, the thinness of the Co barrier layer allows for a higher overall copper line volume leading to lower line resistivity and RC delay.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
forming a cobalt nitride layer on a semiconductor substrate in a reactor, wherein the semiconductor substrate includes a trench etched into a dielectric layer;
forming a cobalt metal layer on the cobalt nitride layer; and
annealing the cobalt nitride layer and the cobalt metal layer to form a graded cobalt barrier layer.

2. The method of claim 1, further comprising:
depositing a metal layer within the trench on the graded cobalt barrier layer, wherein the metal layer functions as a metal interconnect.

3. The method of claim 1, wherein the cobalt nitride layer and the cobalt metal layer are formed using a PVD process.

4. The method of claim 3, wherein the PVD process comprises:
performing a reactive sputtering process using cobalt and a co-reactant to form the cobalt nitride layer; and
performing a sputtering process using cobalt to form the cobalt metal layer.

5. The method of claim 4, wherein the co-reactant comprises at least one of N₂, NH₃, NMe₃, or NEt₃.

6. The method of claim 1, wherein the cobalt nitride layer and the cobalt metal layer are formed using an ALD process.

7. The method of claim 6, wherein the ALD process comprises:
performing a first process cycle comprising:
pulsing a first cobalt precursor into the reactor proximate to the substrate,
purging the reactor after the cobalt precursor pulse,
pulsing a first co-reactant into the reactor proximate to the substrate, wherein the first co-reactant reacts with the first cobalt precursor to form a cobalt nitride layer, and
purging the reactor after the first co-reactant pulse; and
performing a second process cycle comprising:
pulsing a second cobalt precursor into the reactor proximate to the substrate,
purging the reactor after the second cobalt precursor pulse,
pulsing a second co-reactant into the reactor proximate to the substrate, wherein the second co-reactant reacts with the second cobalt precursor to form a cobalt metal layer, and
purging the reactor after the second co-reactant pulse.

8. The method of claim 7, wherein each of the first and the second cobalt precursor are selected from the group consisting of (H)CO(CO)₄, (Me)CO(CO)₄, (Et)CO(CO)₄, (acetyl)CO(CO)₄, (allyl)CO(CO)₃, (1,3 butadiene)CO(CO)₃, crotyl(1-3 butenyl)CO(CO)₃, CO(CO)₃(NO), CO(CO)₂(cycloheptadienyl), [(MeO)₃P]₂CoMe(CO)₂, Me₃Si(Cp)CO(CO)₂, cobaltocene, CPCO(CO)₂, CpCo(hexadiene), CpCo(MeCp), Cp(Co)(CH₃CN), CpCo(PMe₃)₂, CpCo(norboradiene), CpCo(RCp), CpCo(R) (where R═COD, norbornadiene, or two olefins such as ethylene), Cp(Co)duroquinone, (CO)₂(Cp)Co, Co(II)acetylacetonate, bis(N,N′-diisopropylacetamidinato)Co(II), bis(N,N′-disecbutylacetamidinato)Co(II), tris(2,2,6,6-tetramethyl-3,5-heptanedionato)Co(III), CO(allyl)₃, Co(1-methyl-allyl)₃, allylCo(PMe₃)₃, allylCo(CO) (PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (bisindenyl)Co.

9. The method of claim 7, wherein the first co-reactant comprises N₂, NH₃, NMe₃, or NEt₃.

10. The method of claim 7, wherein the second co-reactant comprises hydrogen, carbon monoxide, or a hydrogen plasma.

11. The method of claim 7, further comprising repeating the first process cycle until the cobalt nitride layer has reached a desired thickness.

12. The method of claim 7, further comprising repeating the second process cycle until the cobalt metal layer has reached a desired thickness.

13. The method of claim 1, wherein the cobalt nitride layer and the cobalt metal layer are formed using an ALD co-flow process.

14. The method of claim 13, wherein the ALD co-flow process comprises:
performing a first process cycle comprising:
co-pulsing a first cobalt precursor and a first co-reactant into the reactor proximate to the substrate,
purging the reactor after the first cobalt precursor and first co-reactant co-pulse,
pulsing a second co-reactant into the reactor proximate to the substrate, wherein the first cobalt precursor, the first co-reactant, and the second co-reactant react to form a cobalt nitride layer, and
purging the reactor after the second co-reactant pulse; and
performing a second process cycle comprising:
pulsing a second cobalt precursor into the reactor proximate to the substrate,
purging the reactor after the second cobalt precursor pulse,
pulsing a third co-reactant into the reactor proximate to the substrate, wherein the third co-reactant reacts with the second cobalt precursor to form a cobalt metal layer, and
purging the reactor after the third co-reactant pulse.

15. The method of claim 14, wherein each of the first and the second cobalt precursor are selected from the group consisting of tetracarbonyl derivatives that include, but are not limited to, (H)Co(CO)₄, (Me)Co(CO)₄, (Et)Co(CO)₄, and (acetyl)Co(CO)₄; tricarbonyl derivatives that include, but are not limited to, (allyl)CO(CO)₃, (1,3 butadiene)CO(CO)₃, crotyl(1-3 butenyl)Co(CO)₃, and Co(CO)₃(NO); dicarbonyl derivatives that include, but are not limited to, CO(CO)₂(cycloheptadienyl), [(MeO)₃P]₂CoMe(CO)₂, Me₃Si(Cp)CO(CO)₂; cyclopentadienyl (Cp) containing precursors or derivatives that include, but are not limited to, Cp₂CO (cobaltocene), CPCO(CO)₂, CpCo(hexadiene), CpCo(MeCp), Cp(Co)(CH₃CN), CpCo(PMe₃)₂, CpCo(norboradiene), CpCo(RCp) (where RCp is any derivatized cyclopentadienyl ligand), CpCo(R) (where R=cyclooctadiene (COD), norbornadiene, or two olefins such as ethylene), Cp(Co)duroquinone, and (CO)₂(Cp)Co; and other cobalt containing precursors that include, but are not limited to, Co(II)acetylacetonate, bis(N,N′-diisopropylacetamidinato)Co(II), bis(N,N′-disecbutylacetamidinoto)Co(II), tris(2,2,6,6-tetramethyl-3,5-heptanedionato)Co(III), CO(allyl)₃, Co(1-methyl-allyl)₃, allylCo(PMe₃)₃, allylCo(CO) (PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (indenyl)₂Co.

16. The method of claim 14, wherein the first co-reactant comprises N₂, NH₃, NMe₃, or NEt₃.

17. The method of claim 14, wherein the second co-reactant comprises N₂, NH₃, or a hydrogen plasma.

18. The method of claim 14, wherein the third co-reactant comprises hydrogen, carbon monoxide, or a hydrogen plasma.

19. The method of claim 14, further comprising repeating the first process cycle until the cobalt nitride layer has reached a desired thickness.

20. The method of claim 14, further comprising repeating the second process cycle until the cobalt metal layer has reached a desired thickness.

21. The method of claim 1, wherein the cobalt nitride layer and the cobalt metal layer are formed using a CVD and ALD process.

22. The method of claim 21, wherein the CVD and ALD process comprises:
performing a CVD process cycle comprising:
flowing a first cobalt precursor into the reactor proximate to the substrate, and
flowing a first co-reactant into the reactor proximate to the substrate, wherein the first cobalt precursor reacts with the first co-reactant to form a cobalt nitride layer; and
performing an ALD process cycle comprising:
pulsing a second cobalt precursor into the reactor proximate to the substrate,
purging the reactor after the second cobalt precursor pulse,
pulsing a second co-reactant into the reactor proximate to the substrate, wherein the second co-reactant reacts with the second cobalt precursor to form a cobalt metal layer, and
purging the reactor after the second co-reactant pulse.

23. The method of claim 22, wherein the CVD process cycle further comprises flowing a plasma into the reactor proximate to the substrate, wherein the first cobalt precursor, the first co-reactant, and the plasma react to form the cobalt nitride layer.

24. The method of claim 22, wherein each of the first and the second cobalt precursor are selected from the group consisting of tetracarbonyl derivatives that include, but are not limited to, (H)CO(CO)₄, (Me)CO(CO)₄, (Et)Co(CO)₄, and (acetyl)Co(CO)₄; tricarbonyl derivatives that include, but are not limited to, (allyl)CO(CO)₃, (1,3 butadiene)CO(CO)₃, crotyl(1-3 butenyl)Co(CO)₃, and CO(CO)₃(NO); dicarbonyl derivatives that include, but are not limited to, CO(CO)₂(cycloheptadienyl), [(MeO)₃P]₂CoMe(CO)₂, Me₃Si(Cp)CO(CO)₂; cyclopentadienyl (Cp) containing precursors or derivatives that include, but are not limited to, Cp₂Co (cobaltocene), CpCo(CO)₂, CpCo(hexadiene), CpCo(MeCp), Cp(Co)(CH₃CN), CpCo(PMe₃)₂, CpCo(norboradiene), CpCo(RCp) (where RCp is any derivatized cyclopentadienyl ligand), CpCo(R) (where R═COD, norbornadiene, or two olefins such as ethylene), Cp(Co)duroquinone, and (CO)₂(Cp)Co; and other cobalt containing precursors that include, but are not limited to, Co(II)acetylacetonate, bis(N,N′-diisopropylacetamidinato)Co(II), bis(N,N′-disecbutylacetamidinato)Co(II), tris(2,2,6,6-tetramethyl-3,5-heptanedionato)Co(III), Co(allyl)₃, Co(1-methyl-allyl)₃, allylCo(PMe₃)₃, allylCo(CO)(PMe₃), [(4,4′ ethylenedinitrilo)di-2-pentanato (2-)]methyl cobalt, propynehexacarbonyldicobalt, bis(carbonyl-Cp)dimethyl dicobalt, cyclobutadienyl(Cp)Co, methylidenenonacarbonyltricobalt, cycloheptadienyl(COD)Co, (indenyl)Co(COD), and (indenyl)₂Co.

25. The method of claim 22, wherein the first co-reactant comprises N₂, NH₃, NMe₃, or NEt₃.

26. The method of claim 22, wherein the second co-reactant comprises hydrogen or a hydrogen plasma.

27. The method of claim 22, further comprising continuing the CVD process cycle until the cobalt nitride layer has reached a desired thickness.

28. The method of claim 22, further comprising repeating the ALD process cycle until the cobalt metal layer has reached a desired thickness.

29. The method of claim 2, wherein the depositing of the metal layer comprises:
transferring the semiconductor substrate to a metal plating bath; and
depositing the metal layer on the graded cobalt barrier layer using a plating process.

30. The method of claim 29, wherein the plating bath comprises an electroplating bath and the plating process comprises an electroplating process.

31. The method of claim 29, wherein the plating bath comprises an electroless plating bath and the plating process comprises an electroless plating process.

32. A method comprising:
forming a graded cobalt barrier layer in situ on a semiconductor substrate in a reactor, wherein the semiconductor substrate includes a trench etched into a dielectric layer; and
depositing a metal layer within the trench on the graded cobalt barrier layer, wherein the metal layer functions as a metal interconnect.

33. The method of claim 32, wherein the graded cobalt barrier layer is formed in situ using a PVD process.

34. The method of claim 33, wherein the PVD process comprises a reactive sputtering deposition of cobalt and a nitrogen-containing co-reactant, wherein a flow of the nitrogen-containing co-reactant is attenuated over the course of the reactive sputtering deposition.

35. The method of claim 32, wherein the graded cobalt barrier layer is formed in situ using an ALD process.

36. The method of claim 35, wherein the ALD process includes multiple pulses of a cobalt precursor and a nitrogen-containing co-reactant, wherein the pulses of the nitrogen-containing co-reactant are attenuated over the course of the ALD process.

37. The method of claim 32, wherein the graded cobalt barrier layer is formed in situ using a CVD and an ALD process.

38. The method of claim 37, wherein the CVD process includes flowing a cobalt precursor and a nitrogen-containing co-reactant into the reactor, wherein the nitrogen-containing co-reactant flow is attenuated over the course of the CVD process.
